(19) United States
(12) Patent Application Publication
(10) Pub. No.: US 2024/0096728 A1
(43) Pub. Date: Mar. 21, 2024

(54) SEMICONDUCTOR PACKAGES

(71) Applicant: Samsung Electronics Co., Ltd., Suwon-si (KR)

(72) Inventors: Jin Kyeong Seol, Suwon-si (KR); Hyuek Jae Lee, Suwon-si (KR)

(21) Appl. No.: 18/340,101

(22) Filed: Jun. 23, 2023

(30) Foreign Application Priority Data
Sep. 19, 2022 (KR) 10-2022-0117532

(51) Int. Cl. H01L 23/367; H01L 23/00; H01L 23/31; H01L 25/065; H10B 80/00

(52) U.S. Cl. CPC H01L 23/367; H01L 23/3107; H01L 24/08; H01L 25/0657; H10B 80/00; H01L 2224/08145

(57) ABSTRACT

A semiconductor package is provided. The semiconductor package comprises a first semiconductor die including a memory, a second semiconductor die including a memory and on the first semiconductor die, a dummy die on the semiconductor device and not including a memory, a heat sink on the dummy die and including a metal material and a mold film on side surfaces of each of the first semiconductor die, the second semiconductor die, the dummy die, and the heat sink. A width of the heat sink may decrease away from a top surface of the dummy die, and side surfaces of the heat sink may be curved.

### CROSS-REFERENCE TO RELATED APPLICATION

This application claims priority from Korean Patent Application No. 10-2022-0117532 filed on Sep. 19, 2022, in the Korean Intellectual Property Office, and all the benefits accruing therefrom under 35 U.S.C. § 119, and the entire contents of the above-identified application are incorporated by reference herein.

### BACKGROUND

### 1. Field

The present disclosure relates to semiconductor packages.

### 2. Description of the Related Art

Due to developments in the electronic industry, demand for highly functional, high-speed, and compact-size electronic components has increased. Accordingly, methods may be used in which several semiconductor chips are stacked on a single package wiring structure or a package is stacked on another package.

Meanwhile, as semiconductor devices become highly integrated and high functional, excessive heat may be generated in a semiconductor package. Accordingly, it is desired to improve the heat dissipation performance of a semiconductor package.

### SUMMARY

Aspects of the present disclosure provide a semiconductor package with an improved heat dissipation performance.

However, aspects of the present disclosure are not restricted to those set forth herein. The above and other aspects of the present disclosure will become more apparent to those of ordinary skill in the art to which the present disclosure pertains by referencing the detailed description of the present disclosure given below.

According to some aspects of the present disclosure, there is provided a semiconductor package that may include a first semiconductor die including a first top surface and a first bottom surface, which is opposite to the first top surface; a second semiconductor die including a second bottom surface, which faces the first top surface, and a second top surface, which is opposite to the second bottom surface; a dummy die on the second semiconductor die, a heat sink on the dummy die and including a metal material; and a mold film on side surfaces of each of the first semiconductor die, the second semiconductor die, the dummy die, and the heat sink. Side surfaces of the heat sink may protrude outwardly from a central axis of the heat sink and may be convex toward the outside of the semiconductor package.

According to some aspects of the present disclosure, there is provided a semiconductor package that may include: a first semiconductor die including a memory, a second semiconductor die including a memory and on the first semiconductor die, a dummy die on the second semiconductor die and not including a memory, a heat sink on the dummy die and including a metal material, and a mold film on side surfaces of each of the first semiconductor die, the second semiconductor die, the dummy die, and the heat sink. A width of the heat sink may decrease away from a top surface of the dummy die, and side surfaces of the heat sink may be curved.

According to some aspects of the present disclosure, there is provided a semiconductor package that may include: a first semiconductor die including a memory, a first top surface, and a first bottom surface, which is opposite to the first top surface; upper connection pads on the first top surface; a second semiconductor die including a memory, a second bottom surface, which faces the first top surface, and a second top surface, which is opposite to the second bottom surface; lower connection pads on the second bottom surface and in contact with the upper connection pads, a dummy die on the second semiconductor die and not including a memory; a heat sink on the dummy die and in contact with a top surface of the dummy die and including a metal material; and a mold film on side surfaces of each of the first semiconductor die, the second semiconductor die, the dummy die, and the heat sink. A top surface of the mold film and a top surface of the heat sink may be coplanar, and side surfaces of the heat sink may protrude outwardly from a central axis of the heat sink and may be convex toward an outside of the semiconductor package.

It should be noted that the present disclosure is not limited to the aspects described above, and other aspects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view of a semiconductor package according to some embodiments of the present disclosure.

FIG. 2 is a cross-sectional view of the semiconductor package of FIG. 1.

FIG. 3 is a cross-sectional view of a semiconductor package according to some embodiments of the present disclosure.

FIG. 4 is an enlarged cross-sectional view of part P of FIG. 3.

FIG. 5 is a cross-sectional view of a semiconductor package according to some embodiments of the present disclosure.

FIG. 6 is a plan view of a semiconductor package according to some embodiments of the present disclosure.

FIG. 7 is a cross-sectional view of the semiconductor package of FIG. 6.

FIG. 8 is a cross-sectional view of the semiconductor package of FIG. 6.

FIG. 9 is a cross-sectional view of a semiconductor packages according to some embodiments of the present disclosure.

FIGS. 10 through 17 are cross-sectional views illustrating a method of fabricating a semiconductor package according to some embodiments of the present disclosure.

### DETAILED DESCRIPTION

Embodiments of the present disclosure will be described with reference to the attached drawings.

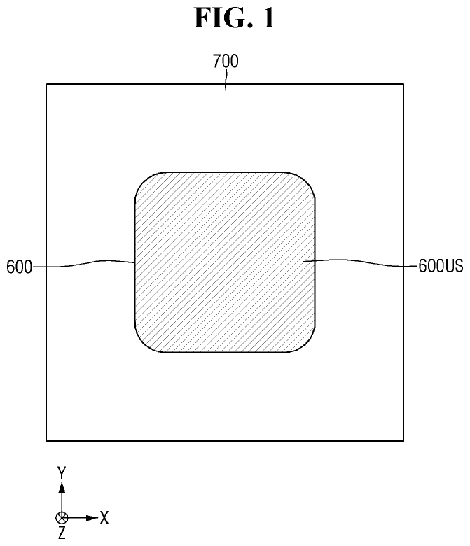

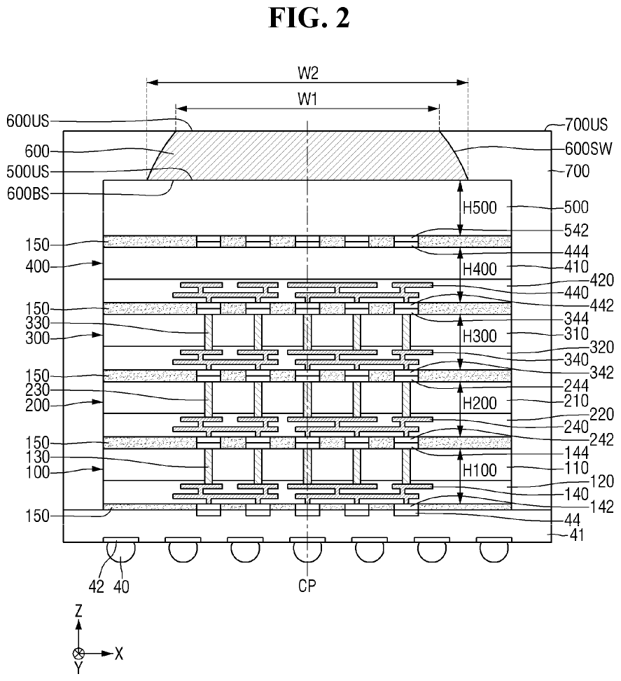

FIG. 1 is a plan view of a semiconductor package according to some embodiments of the present disclosure. FIG. 2 is a cross-sectional view of the semiconductor package of FIG. 1.

Referring to FIGS. 1 and 2, the semiconductor package may include first, second, third, and fourth semiconductor dies 100, 200, 300, and 400, a base substrate 41, a dummy die 500, a heat sink 600, and a mold film 700.

The first, second, third, and fourth semiconductor dies 100, 200, 300, and 400 may be logic chips or memory chips. The first, second, third, and fourth semiconductor dies 100, 200, 300, and 400 may be memory chips of the same type. For example, the first, second, third, and fourth semiconductor dies 100, 200, 300, and 400 may be volatile memory chips such as dynamic random access memories (DRAMs) or static random access memories (SRAMs). In another example, the first, second, third, and fourth semiconductor dies 100, 200, 300, and 400 may be nonvolatile memory chips such as phase-change random-access memories (PRAMs), magnetoresistive random-access memories (MRAMs), ferroelectric random-access memories (FeRAMs), or resistive random-access memories (RRAMs). In another example, the first, second, third, and fourth semiconductor dies 100, 200, 300, and 400 may be high-bandwidth memories (HBMs). In some embodiments, the first, second, third, and fourth semiconductor dies 100, 200, 300, and 400 may include a combination of volatile memory chips and nonvolatile memory chips. In some embodiments, the first, second, third, and fourth semiconductor dies 100, 200, 300, and 400 may include memories. The first, second, third, and fourth semiconductor dies 100, 200, 300, and 400 may include DRAMs.

Some of the first, second, third, and fourth semiconductor dies 100, 200, 300, and 400 may be memory chips, and some of the first, second, third, and fourth semiconductor dies 100, 200, 300, and 400 may be logic chips. For example, some of the first, second, third, and fourth semiconductor dies 100, 200, 300, and 400 may be microprocessors, analog devices, digital signal processors (DSPs), or application processors (APs).

The first semiconductor die 100 may include a first semiconductor substrate 110, a first semiconductor device layer 120, first through electrodes 130, first lower connection pads 142, and first upper connection pads 144.

In an example, the first semiconductor substrate 110 may be a bulk silicon or silicon-on-insulator (SOI) substrate. In another example, the first semiconductor substrate 110 may be a silicon (Si) substrate. In another example, the first semiconductor substrate 110 may include silicon germanium, silicon germanium-on-insulator (SGOI), indium antimonide, a lead tellurium compound, indium arsenide, indium phosphide, gallium arsenide, or gallium antimonide, but the present disclosure is not limited thereto.

The first semiconductor substrate 110 may include a conductive region, for example, a well or structure doped with impurities. The first semiconductor substrate 110 may have various device isolation structures such as a shallow trench isolation (STI) structure.

The first semiconductor device layer 120 may be on the bottom surface of the first semiconductor substrate 110. The first semiconductor device layer 120 may include various types of individual devices and interlayer insulating films. Examples of the individual devices include various microelectronic devices, for example, metal-oxide-semiconductor field-effect transistors (MOSFETs) such as complementary metal-oxide-semiconductor (CMOS) transistors, system large-scale integration (LSI), flash memories, DRAMs, SRAMs, electrically erasable programmable read-only memories (EEPROMs), PRAMs, MRAMs, RRAMs, image sensors such as CMOS image sensors, micro-electro-mechanical systems (MEMSs), active elements, passive elements, and the like.

The individual devices of the first semiconductor device layer 120 may be electrically connected to the conductive area formed in the first semiconductor substrate 110. The individual devices of the first semiconductor device layer 120 may be electrically isolated from other individual devices by insulating films. The first semiconductor device layer 120 may include a first wiring structure 140, which may electrically connect at least two of the individual devices to the conductive area of the first semiconductor substrate 110.

Although not specifically illustrated, a lower passivation layer, which may be provided as a protection for the first wiring structure in the first semiconductor device layer 120 from external shock or moisture, may be formed on the first semiconductor layer 120. The lower passivation layer may expose parts of the top surfaces of the first lower connection pads 142.

The first through electrodes 130 may penetrate or extend through the first semiconductor substrate 110. The first through electrodes 130 may extend from the top surface to the bottom surface of the first semiconductor substrate 110. The first through electrodes 130 may be connected to the first wiring structure 140 in the first semiconductor device layer 120.

The first through electrodes 130 may include barrier films, which may be formed on the surfaces of pillars or other components, and buried conductive layers, which may fill or be within the barrier films. The barrier films may include at least one of titanium (Ti), titanium nitride (TiN), tantalum (Ta), tantalum nitride (TaN), ruthenium (Ru), cobalt (Co), manganese (Mn), tungsten nitride (WN), nickel (Ni), and/or nickel boride (NiB), but the present disclosure is not limited thereto. The buried conductive layers may include at least one of Cu, an alloy of Cu (e.g., CuSn, CuMg, CuNi, CuZn, CuPd, CuAu, CuRe, or CuW), tungsten (W), an alloy of W, Ni, Ru, and/or Co, but the present disclosure is not limited thereto.

In some embodiments, an insulating film may be interposed between the first semiconductor substrate 110 and the first through electrodes 130. The insulating film may include an oxide film, a nitride film, a carbide film, a polymer, or a combination thereof, but the present disclosure is not limited thereto.

The first wiring structure 140 may include metal wiring layers and via plugs. For example, the first wiring structure 140 may have a multilayer structure in which two or more metal layers and two or more via plugs are alternately stacked.

The first lower connection pads 142 may be on the first semiconductor device layer 120. The first lower connection pads 142 may be electrically connected to the first wiring structure 140 in the first semiconductor device layer 120. The first lower connection pads 142 may be electrically connected to the first through electrodes 130 through the first wiring structure 140. The first lower connection pads 142 may include at least one of aluminum (Al), Cu, Ni, W, platinum (Pt), or gold (Au).

The first upper connection pads 144, which are electrically connected to the first through electrodes 130, may be formed on the top surface of the first semiconductor substrate 110. The first upper connection pads 144 may be formed of the same material as the first lower connection pads 142. The first lower connection pads 142 may be on a first side (e.g., a lower side) of the first semiconductor substrate 110, and the first upper connection pads 144 may be on a second side (e.g., an upper side) of the first semiconductor substrate 110 that is opposite from the first side. Although not specifically illustrated, an upper passivation layer may be formed on the top surface of the first semiconductor substrate 110 to surround parts of the lateral sides of each of the first through electrodes 130.

The second semiconductor die 200 may include a second semiconductor substrate 210 and a second semiconductor device layer 220, which may include a second wiring structure 240, and the second semiconductor die 200 may also include second through electrodes 230, second lower connection pads 242, and second upper connection pads 244. The components of the second semiconductor die 200 may be similar to like components of the first semiconductor die 100, and duplicative description thereof is omitted here in the interest of brevity.

The second semiconductor die 200 may be on the first semiconductor die 100. The second semiconductor die 200 may be electrically connected to the first semiconductor die 100 through the first upper connection pads 144 and the second lower connection pads 242, which are between the first and second semiconductor substrates 110 and 210. The first upper connection pads 144 and the second lower connection pads 242 may be in direct contact with one another.

An insulating layer 150 may be between the top surface of the first semiconductor substrate 110 and the bottom surface of the second semiconductor substrate 210. The insulating layer 150 may attach the second semiconductor die 200 onto the first semiconductor die 100. The insulating layer 150 may surround the first upper connection pads 144 and the second lower connection pads 242, which are between the first and second semiconductor substrates 110 and 210.

The third semiconductor die 300 may be on the second semiconductor die 200. The third semiconductor die 300 may include a third semiconductor substrate 310 and a third semiconductor device layer 320, which includes a third wiring structure 340, and may also include third through electrodes 330, third lower connection pads 342, and third upper connection pads 344. The components of the third semiconductor die 300 may be similar to like components of the first semiconductor die 100, and duplicative description thereof is omitted here in the interest of brevity.

The fourth semiconductor die 400 may be on the third semiconductor die 300. The fourth semiconductor die 400 may include a fourth semiconductor substrate 410 and a fourth semiconductor device layer 420, which includes a fourth wiring structure 440, and may also include fourth lower connection pads 442 and fourth upper connection pads 444. The components of the fourth semiconductor die 400 may be similar to like components of the first semiconductor die 100, and duplicative description thereof is omitted here in the interest of brevity, except that the fourth semiconductor die 400, unlike the first, second, and third semiconductor dies 100, 200, and 300, may not include through electrodes. However, the present disclosure is not limited thereto, and thus in some embodiments the fourth semiconductor die 400 may include through electrodes.

The first, second, third, and fourth semiconductor dies 100, 200, 300, and 400 may be stacked vertically on the base substrate 41. The first, second, third, and fourth semiconductor dies 100, 200, 300, and 400 may be electrically connected through the first lower connection pads 142, the second lower connection pads 242, the third lower connection pads 342, and the fourth lower connection pads 442 and the first upper connection pads 144, the second upper connection pads 244, the third upper connection pads 344, and the fourth upper connection pads 444.

An insulating layer 150 may be between the top surface of the second semiconductor substrate 210 and the bottom surface of the third semiconductor substrate 310. The insulating layer 150 may surround the second upper connection pads 244 and the third lower connection pads 342, which may be between the second and third semiconductor substrates 210 and 310.

An insulating layer 150 may be between the top surface of the third semiconductor substrate 310 and the bottom surface of the fourth semiconductor substrate 410. The insulating layer 150 may surround the third upper connection pads 344 and the fourth lower connection pads 442, which may be between the third and fourth semiconductor substrates 310 and 410.

The base substrate 41 may be, for example, a printed circuit board (PCB), a ceramic substrate, or an interposer. Alternatively, the base substrate 41 may be a semiconductor chip including semiconductor elements. The base substrate 41 may function as a support substrate for the semiconductor package. For example, the first, second, third, and fourth semiconductor dies 100, 200, 300, and 400 may be stacked on the base substrate 41.

The base substrate 41 may include bottom pads 42 and top pads 44. The bottom pads 42 may be on the bottom surface of the base substrate 41. The top pads 44 may be on the top surface of the base substrate 41. External connection terminals 40 may be below the base substrate 41. The external connection terminals 40 may be on the bottom pads 42. For example, the external connection terminals 40 may be solder balls or bumps.

An insulating layer 150 may be formed between the base substrate 41 and the first semiconductor substrate 110. The insulating layer 150 may surround the first lower connection pads 142, between the base substrate 41 and the first semiconductor substrate 110.

The dummy die 500 may be on the fourth semiconductor die 400. The dummy die 500 may be electrically connected to the fourth semiconductor die 400 through fifth lower connection pads 542 and the fourth upper connection pads 444. An insulating layer 150 may be between the dummy die 500 and the fourth semiconductor substrate 400. The insulating layer 150 may surround the fifth lower connection pads 542 and the fourth upper connection pads 444, which are between the dummy die 500 and the fourth semiconductor substrate 410.

The dummy die 500 may not include a memory. For example, the dummy die 500 may not be a volatile memory chip such as a DRAM or an SRAM. The dummy die 500 may also not be a nonvolatile memory chip such as a PRAM, an MRAM, an FeRAM, or an RRAM.

The dummy die 500 may include Si.

The thickness of the dummy die 500 may be the same as the thicknesses of the first, second, third, and fourth semiconductor dies 100, 200, 300, and 400. Alternatively, the thickness of the dummy die 500 may be greater than the thicknesses of the first, second, third, and fourth semiconductor dies 100, 200, 300, and 400.

The first, second, third, and fourth semiconductor dies 100, 200, 300, and 400 may have first, second, third, and fourth thicknesses H100, H200, H300, and H400, respectively. The first, second, third, and fourth thicknesses H100, H200, H300, and H400 may all be the same, but the present disclosure is not limited thereto. Alternatively, the first, second, third, and fourth thicknesses H100, H200, H300, and H400 may differ from one another.

The dummy die 500 may have a fifth thickness H500. The fifth thickness H500 may be greater than, or the same as, the first, second, third, and fourth thicknesses H100, H200, H300, and H400. For example, the fifth thickness H500 may be one to five times the first, second, third, and fourth thicknesses H100, H200, H300, and H400.

The heat sink 600 may be on the dummy die 500. The heat sink 600 may be in direct contact with the dummy die 500. A bottom surface 600BS of the heat sink 600 may be in direct contact with a top surface 500US of the dummy die 500. The bottom surface 600BS of the heat sink 600 and the top surface 500US of the dummy die 500 may be on the same plane. The bottom surface 600BS of the heat sink 600 may be smaller than the top surface 500US of the dummy die 500. That is, the bottom surface 600BS of the heat sink 600 may cover part of the top surface 500US of the dummy die 500.

In a plan view (e.g., as seen in FIG. 1), the heat sink 600 may have a rectangular shape with rounded or curved corners. That is, a top surface 600US of the heat sink 600 may have a rectangular shape with rounded or curved corners. Also, the bottom surface 600BS of the heat sink 600 may have a rectangular shape with rounded or curved corners.

The top surface 600US of the heat sink 600 may be smaller in one or more dimensions than the bottom surface 600BS of the heat sink 600. The width of the heat sink 600 may decrease away from the dummy die 500. That is, the width of the heat sink 600 may decrease away from the top surface 500US of the dummy die 500.

The top surface 600US of the heat sink 600 may have a first width W1. The bottom surface 600BS of the heat sink 600 may have a second width W2. The first width W1 may be less than the second width W2. For example, the first width W1 may be 50% to 90% of the second width W2.

Side surfaces 600SW of the heat sink 600 may be curved. The side surfaces 600SW of the heat sink 600 may be convexly curved with respect to a central axis CP of the heat sink 600.

The mold film 700 may be formed on the base substrate 41. The mold film 700 may cover the insulating layers 150, the first, second, third, and fourth semiconductor dies 100, 200, 300, and 400, the dummy die 500, and the heat sink 600. Specifically, the mold film 700 may surround side surfaces of each of the insulating layers 150, the first, second, third, and fourth semiconductor dies 100, 200, 300, and 400, the dummy die 500, and the heat sink 600. Also, the mold film 700 may cover part of the top surface 500US of the dummy die 500.

The mold film 700 may include, for example, a polymer such as resin. For example, the mold film 700 may include an epoxy molding compound (EMC), but the present disclosure is not limited thereto.

In a plan view (e.g., as seen in FIG. 1), the mold film 700 may surround the heat sink 600. That is, a top surface 700US of the mold film 700 may surround the top surface 600US of the heat sink 600.

The top surface 700US of the mold film 700 and the top surface 600US of the heat sink 600 may be on the same plane. The top surface 700US of the mold film 700 may not cover the top surface 600US of the heat sink 600. That is, the top surface 600US of the heat sink 600 may not overlap with the top surface 700US of the mold film 700.

The top surface 600US of the heat sink 600 may be exposed from the top surface 700US of the mold film 700. As the top surface 600US of the heat sink 600 is exposed, the heat dissipation performance of the heat sink 600 can be improved.

Part of the top surface 500US of the dummy die 500 that does not overlap vertically with the bottom surface 600BS of the heat sink 600 may be covered by the mold film 700.

The heat sink 600 may include a metal material. Accordingly, the heat sink 600 may have thermal conductivity. The heat sink 600 may release heat generated by the first, second, third, and fourth semiconductor dies 100, 200, 300, and 400 and the dummy die 500. As the top surface 600US of the heat sink 600 is not covered by the mold film 700, the heat sink 600 can easily release heat to the outside.

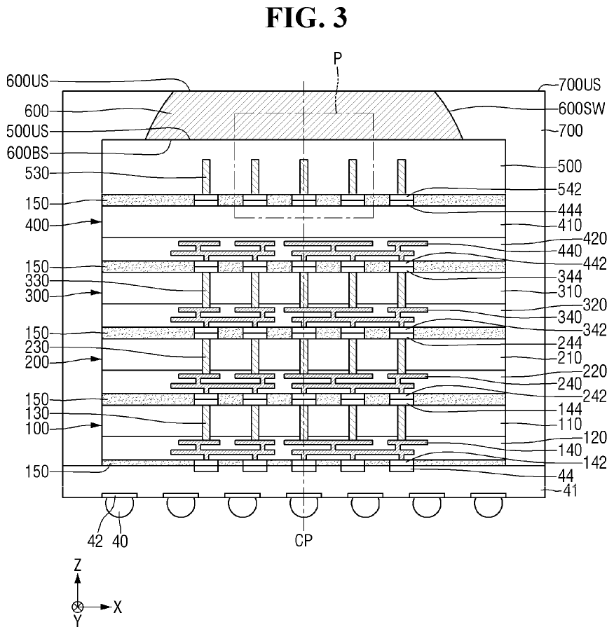

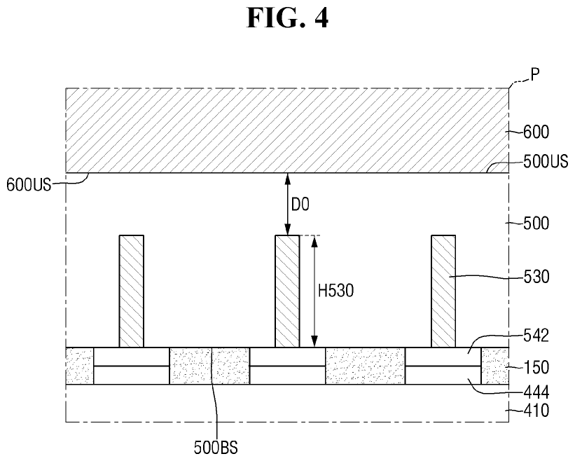

FIG. 3 is a cross-sectional view of a semiconductor package according to some embodiments of the present disclosure. FIG. 4 is an enlarged cross-sectional view of part P of FIG. 3. For convenience, the embodiments of FIGS. 3 and 4 will be described by focusing mainly on the differences with the embodiments of FIG. 2.

Referring to FIGS. 3 and 4, the semiconductor package may include fifth electrodes 530. The fifth electrodes 530 may be vertical electrodes. The fifth electrodes 530 may be used to transmit electrical signals to or between, first, second, third, and fourth semiconductor dies 100, 200, 300, and 400. For example, the fifth electrodes 530 may be used to provide electrical signals to the first semiconductor die 100. In another example, the fifth electrodes 530 may be used to transmit signals from the fourth semiconductor die 400 to the third semiconductor die 300.

The fifth electrodes 530 may extend through only part of a dummy die 500. The bottom surfaces of the electrodes 530 may be on the same plane as a bottom surface 500BS of the dummy die 500. The top surfaces of the fifth electrodes 530 may be lower than the top surfaces of the fifth electrodes 530. That is, a top surface 500US of the dummy die 500 may be above the top surfaces of the fifth electrodes 530. The top surfaces of the fifth electrodes 530 may not be exposed at the top of the dummy die 500. The top surface 500US of the dummy die 500 may overlap with the top surfaces of the fifth electrodes 530.

The top surface 500US of the dummy die 500 and the top surfaces of the fifth electrodes 530 may not be in contact with one another. The top surface 500US of the dummy die 500 and the top surfaces of the fifth electrodes 530 may be spaced apart from one another. A bottom surface 600BS of a heat sink 600 and the top surfaces of the fifth electrodes 530 may be spaced apart from one another. Accordingly, the heat sink 600 and the fifth electrodes 530 may not be electrically connected.

A height H530 of the fifth electrodes 530 may be less than the distance between the bottom surface 600BS of the heat sink 600 and the bottom surface 500BS of the dummy die 500. A distance DO between the top surface 500US of the dummy die 500 and the top surfaces of the fifth electrodes 530 may be 5 μm or greater. The distance between the bottom surface 600BS of the heat sink 600 and the top surfaces of the fifth electrodes 530 may be 5 μm or greater.

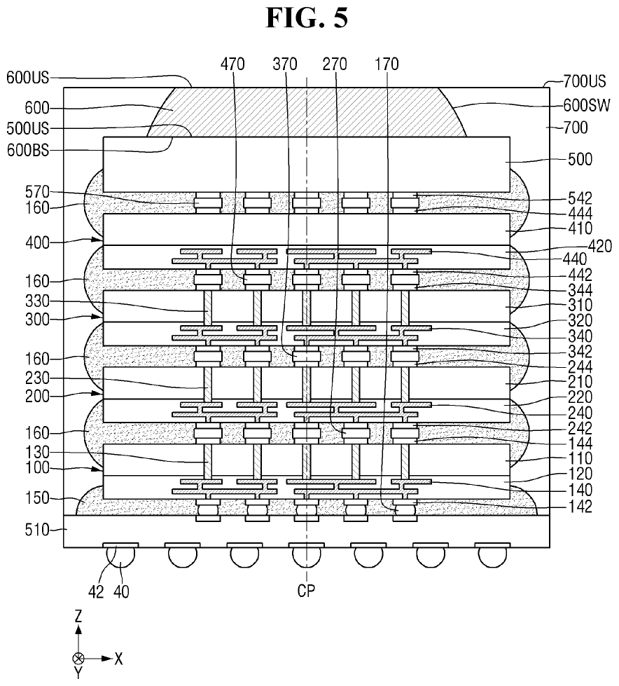

FIG. 5 is a cross-sectional view of a semiconductor package according to some embodiments of the present disclosure. For convenience, the embodiment of FIG. 5 will hereinafter be described, focusing mainly on the differences with the embodiments of FIGS. 2 and 3.

Referring to FIG. 5, first, second, third, and fourth semiconductor dies 100, 200, 300, and 400 may be electrically connected to one another through first connection bumps 170, second connection bumps 270, third connection bumps 370, and fourth connection bumps 470 or may be electrically connected to a base substrate 41. A dummy die 500 may be electrically connected to the fourth semiconductor die 400 through fifth connection bumps 570.

The first semiconductor die 100 may include the first connection bumps 170. The second semiconductor die 200 may include the second connection bumps 270. The third semiconductor die 300 may include the third connection bumps 370. The fourth semiconductor die 400 may include the fourth connection bumps 470. The dummy die 500 may include the fifth connection bumps 570.

The first connection bumps 170 may be in contact with first lower connection pads 142. The first connection bumps 170 may electrically connect the first semiconductor die 100 and a base substrate 41. The first connection bumps 170 may receive control signals, power signals, or ground signals for operating the first, second, third, and fourth semiconductor dies 100, 200, 300, and 400 from the outside. The first connection bumps 170 may receive data signals to be stored in the first, second, third, and fourth semiconductor dies 100, 200, 300, and 400 from the outside. The first connection bumps 170 may provide data stored in the first, second, third, and fourth semiconductor dies 100, 200, 300, and 400 to the outside. For example, the first connection bumps 170 may have a pillar structure or a ball structure or consist of a solder layer.

A fillet layer 160 may be formed between the base substrate 41 and the first semiconductor die 100. The fillet layer 160 may surround the first connection bumps 170 and the first lower connection pads 142, between the base substrate 41 and the first semiconductor die 100.

Fillet layers 160 may be between the first, second, third, and fourth semiconductor dies 100, 200, 300, and 400 and a dummy die 500. For example, a fillet layer 160 may be between the top surface of the first semiconductor die 100 and the bottom surface of the second semiconductor die 200 and may attach the second semiconductor die 200 onto the first semiconductor die 100. The fillet layer 160 between the first and second semiconductor dies 100 and 200 may surround first upper connection pads 144, second connection bumps 270, and second lower connection pads 242, which are between the first and second semiconductor dies 100 and 200.

The fillet layer 160 between the first and second semiconductor dies 100 and 200 may protrude outwardly from the side surfaces of each of the first and second semiconductor dies 100 and 200. The fillet layer 160 between the first and second semiconductor dies 100 and 200 may cover parts of the side surfaces of each of the first and second semiconductor dies 100 and 200. The fillet layer 160 between the first and second semiconductor dies 100 and 200 may have curved side surfaces.

The fillet layers 160 between the second, third, and fourth semiconductor dies 200, 300, and 400 may be substantially the same as, or similar to, the fillet layer 160 between the first and second semiconductor dies 100 and 200, and thus, detailed descriptions thereof will be omitted.

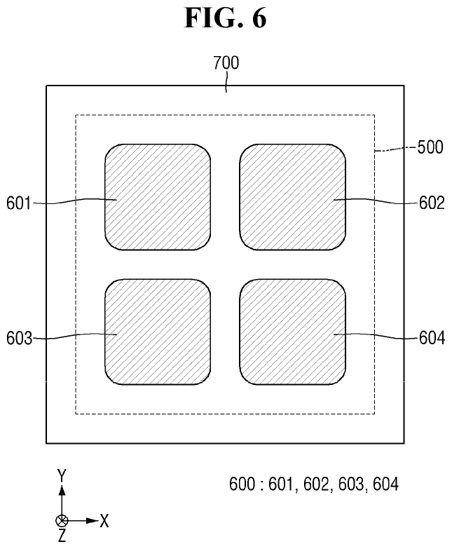

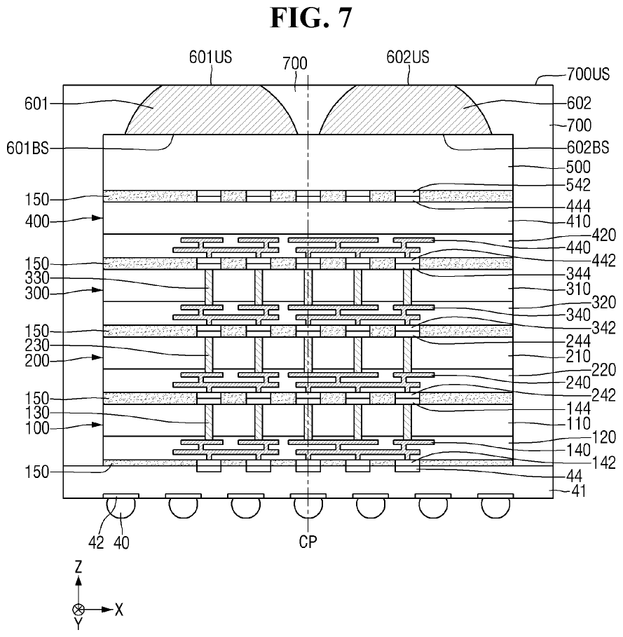

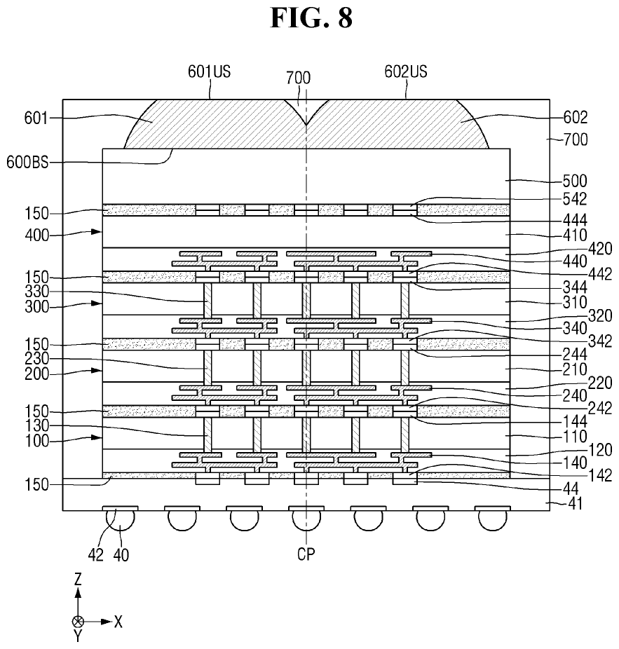

FIG. 6 is a plan view of a semiconductor package according to some embodiments of the present disclosure. FIG. 7 is a cross-sectional view of the semiconductor package of FIG. 6. FIG. 8 is a cross-sectional view of the semiconductor package of FIG. 6. For convenience, the embodiment of FIGS. 6 through 8 will hereinafter be described, focusing mainly on the differences with the embodiments of FIGS. 1 through 5.

Referring to FIGS. 6 and 7, the semiconductor package may include a plurality of heat sinks 600, for example, first, second, third, and fourth heat sinks 601, 602, 603, and 604.

The first, second, third, and fourth heat sinks 601, 602, 603, and 604 may be surrounded by a mold film 700. In a plan view, the top surfaces of the first, second, third, and fourth heat sinks 601, 602, 603, and 604 may be surrounded by a top surface 700US of the mold film 700. The side surfaces of each of the first, second, third, and fourth heat sinks 601, 602, 603, and 604 may be covered by the mold film 700.

A bottom surface 601BS of the first heat sink 601 and a bottom surface 602BS of the second heat sink 602 may be on the same plane. The bottom surface 601BS of the first heat sink 601 and the bottom surface 602BS of the second heat sink 602 may be disposed on the same plane as a top surface 500US of a dummy die 500.

A top surface 601US of the first heat sink 601 and a top surface 602US of the second heat sink 602 may be on the same plane as the top surface 700US of the mold film 700. That is, the top surface 601US of the first heat sink 601 and the top surface 602US of the second heat sink 602 may not be covered by the top surface 700US of the mold film 700. The top surface 601US of the first heat sink 601 and the top surface 602US of the second heat sink 602 may not overlap with the top surface 700US of the mold film 700.

Referring to FIGS. 6 and 7, in some embodiments the first and second heat sinks 601 and 602 may be spaced apart from each other. The bottom surface 601BS of the first heat sink 601 and the bottom surface 602BS of the second heat sink 602 may be spaced apart from each other. The mold film 700 may be in the gap between the first and second heat sinks 601 and 602.

Referring to FIGS. 6 and 8, in some embodiments the first and second heat sinks 601 and 602 may be connected. The bottom surfaces of the first and second heat sinks 601 and 602 may be connected. Top surfaces 601US and 602US of the first and second heat sinks 601 and 602 may be spaced apart from each other. The mold film 700 may be in the gap between the top surfaces 601US and 602US of the first and second heat sinks 601 and 602. The mold film 700 may not be in contact with the top surface of a dummy die 500, in the gap between the top surfaces 601US and 602US of the first and second heat sinks 601 and 602.

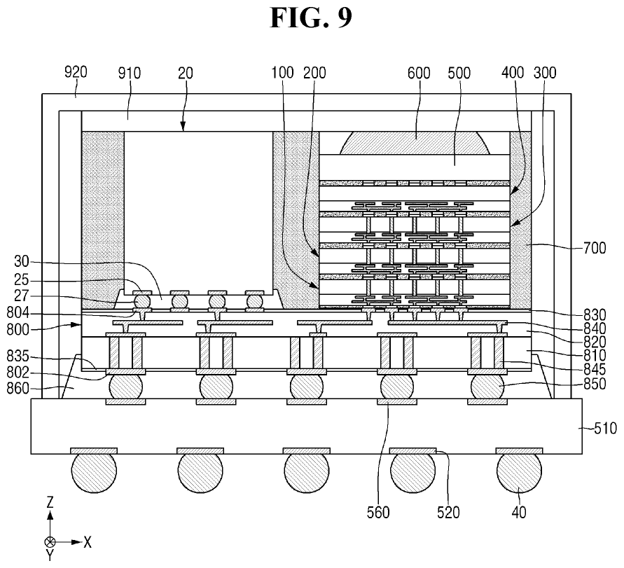

FIG. 9 is a cross-sectional view of a semiconductor packages according to some embodiments of the present disclosure. For convenience, the embodiment of FIG. 9 will hereinafter be described, focusing mainly on the differences with the embodiments of FIGS. 1 through 11.

Referring to FIG. 9, the semiconductor package may further include a fifth semiconductor die 20.

The fifth semiconductor die 20 may be spaced apart horizontally from first, second, third, and fourth semiconductor dies 100, 200, 300, and 400, a dummy die 500, and a heat sink 600. For example, the fifth semiconductor die 20 may be spaced apart from the first, second, third, and fourth semiconductor dies 100, 200, 300, and 400 in a first horizontal direction X.

A base substrate 41 may be a substrate for a package. The base substrate 41 may be a PCB. The base substrate 41 may have a bottom surface and a top surface that are opposite to each other. The top surface of the base substrate 41 may face an interposer structure 800.

The base substrate 41 may include bottom pads 42 and top pads 44. The bottom pads 42 and the top pads 44 may be used to electrically connect the base substrate 41 and other elements. For example, the bottom pads 42 may be exposed from the bottom surface of the base substrate 41, and the top pads 44 may be exposed from the top surface of the base substrate 41. The bottom pads 42 and the top pads 44 may include a metal material such as, for example, copper (Cu) or aluminum (Al), but the present disclosure is not limited thereto.

Wiring patterns for electrically connecting the bottom pads 42 and the top pads 44 may be formed in the base substrate 41. The base substrate 41 is illustrated as being a single layer, but the present disclosure is not limited thereto. Alternatively, the substrate 510 may be formed as a multilayer, and multilayer wiring patterns may be formed in the base substrate 41.

The base substrate 41 may be mounted on, for example, the main board of an electronic device. For example, external connection terminals 40, which are connected to the bottom pads 42, may be provided. The base substrate 41 may be mounted on the main board of an electronic device through the external connection terminals 40. The base substrate 41 may be a ball grid array (BGA) substrate, but the present disclosure is not limited thereto.

In some embodiments, the base substrate 41 may include a copper clad laminate (CCL). For example, the base substrate 41 may have a structure in which a copper laminate is laminated on one or both sides of thermoset prepreg (e.g., C-Stage prepreg).

The interposer structure 800 may be on the top surface of the base substrate 41. The interposer structure 800 may have a bottom surface and a top surface that are opposite to each other. The top surface of the interposer structure 800 may face the first, second, third, and fourth semiconductor dies 100, 200, 300, and 400 and the fifth semiconductor die 20. The bottom surface of the interposer structure 800 may face the base substrate 41. The interposer structure 800 can facilitate connecting the base substrate 41, the first, second, third, and fourth semiconductor dies 100, 200, 300, and 400, and the fifth semiconductor die 20 and can prevent the warpage of the semiconductor package.

The interposer structure 800 may include an interposer 810, an interlayer insulating layer 820, a first passivation film 830, a second passivation film 835, wiring patterns 840, interposer vias 845, first interposer pads 802, and second interposer pads 804.

The interposer 810 may be provided on the base substrate 41. The interposer 810 may be, for example, a silicon (Si) interposer, but the present disclosure is not limited thereto. The interlayer insulating layer 820 may be on the interposer 810. The interlayer insulating layer 820 may include an insulating material. For example, the interlayer insulating layer 820 may include at least one of, for example, silicon oxide, silicon nitride, silicon oxynitride, or a low-k material having a lower dielectric constant than silicon oxide, but the present disclosure is not limited thereto.

The first interposer pads 802 and the second interposer pads 804 may be used to electrically connect the interposer 800 to other elements. For example, the first interposer pads 802 may be exposed from the bottom surface of the interposer structure 800, and the second interposer pads 804 may be exposed from the top surface of the interposer structure 800. The first interposer pads 802 and the second interposer pads 804 may include a metal material such as, for example, Cu or Al, but the present disclosure is not limited thereto. Wiring patterns 840 for electrically connecting the first interposer pads 802 and the second interposer pads 804 may be formed in the interposer structure 800.

For example, wiring patterns 840 and the interposer vias 845 may be formed in the interposer structure 800. The wiring patterns 840 may be in the interlayer insulating layer 820. The interposer vias 845 may penetrate or extend through the interposer 810. Accordingly, the wiring patterns 840 and the interposer vias 845 may be connected to one another. The wiring patterns 840 may be electrically connected to the second interposer pads 804. The interposer vias 845 may be electrically connected to the first interposer pads 802. Accordingly, the interposer structure 800, the first, second, third, and fourth semiconductor dies 100, 200, 300, and 400, and the fifth semiconductor die 20 may be electrically connected to one another. The wiring patterns 840 and the interposer vias 845 may include a metal material such as Cu or Al, but the present disclosure is not limited thereto.

The interposer structure 800 may be mounted on the top surface of the base substrate 41. For example, first connection members 850 may be formed between the base substrate 41 and the interposer structure 800. The first connection members 850 may connect the top pads 44 and the first interposer pads 802. Accordingly, the base substrate 41 and the interposer structure 800 may be electrically connected to each other.

The first connection members 850 may be solder bumps including a low-melting-point metal such as, for example, tin (Sn) and an alloy of Sn, but the present disclosure is not limited thereto. The first connection members 850 may have various shapes such as a land shape, a ball shape, a pin shape, or a pillar shape. The first connection members 850 may be formed as single layers or multilayers. The first connection member 850 may be formed as single layers including, for example, Sn-silver (Ag) solder or Cu. Alternatively, the first connection members 850 may be formed as multilayers including, for example, a Cu filler and solder. The number of first connection members 850, the distance between the first connection members 850, and the layout of the first connection members 850 are not particularly limited and may vary depending on the design of the semiconductor package.

In some embodiments, the size of the external connection terminals 40 may be greater than the size of the first connection members 850. For example, the volume of the external connection terminals 40 may be greater than the volume of the first connection members 850.

The first passivation film 830 may be on the interlayer insulating layer 820. The first passivation film 830 may extend along the top surface of the interlayer insulating layer 820. The second interposer pads 804 may penetrate the first passivation film 830 and may thus be connected to the wiring patterns 840. The second passivation film 835 may be on the interposer 810. The second passivation film 835 may extend along the bottom surface of the interposer 810. The first interposer pads 802 may penetrate the second passivation film 835 and may thus be connected to the interposer vias 845.

In some embodiments, the height, in a third direction Z, of the first passivation film 830 may be less than the height, in the third direction Z, of the second interposer pads 804. The second interposer pads 804 may protrude in the third direction Z beyond the first passivation film 830, but the present disclosure is not limited thereto. The height, in the third direction Z, of the second passivation film 835 may be less than the height, in the third direction Z, of the first interposer pads 802. The first interposer pads 802 may protrude in the third direction Z beyond the second passivation film 835, but the present disclosure is not limited thereto.

The first and second passivation films 830 and 835 may include silicon nitride. Alternatively, the first and second passivation films 830 and 835 may include a passivation material, benzocyclobutene (BCB), polybenzoxazole, polyimide, epoxy, silicon oxide, silicon nitride, or a combination thereof.

In some embodiments, first underfill 860 may be formed between the base substrate 41 and the interposer structure 800. The first underfill 860 may fill the space between the base substrate 41 and the interposer structure 800. The first underfill 860 may cover the first connection members 850. The first underfill 860 may prevent breakage of the interposer structure 800 by fixing the interposer structure 800 on the base substrate 41. The first underfill 860 may include, for example, an insulating polymer material such as an EMC, but the present disclosure is not limited thereto.

In some embodiments, the fifth semiconductor die 20 may be a logic chip. For example, the fifth semiconductor die 20 may be an AP such as a central processing unit (CPU), a graphics processing unit (GPU), a field-programmable gate array (FPGA), a digital signal processor (DSP), a cryptographic processor, a microprocessor, a microcontroller, or an application-specific integrated circuit (ASIC), but the present disclosure is not limited thereto.

In some embodiments, the first, second, third, and fourth semiconductor dies 100, 200, 300, and 400 may include memories. The first, second, third, and fourth semiconductor dies 100, 200, 300, and 400 may be memory chips. For example, the first, second, third, and fourth semiconductor dies 100, 200, 300, and 400 may be volatile memories such as DRAMs or SRAMs. In another example, the first, second, third, and fourth semiconductor dies 100, 200, 300, and 400 may be nonvolatile memories such as flash memories, PRAMs, MRAMs, FeRAMs, or RRAMs. In another example, the first, second, third, and fourth semiconductor dies 100, 200, 300, and 400 may include both volatile and nonvolatile memories.

For example, the fifth semiconductor die 20 may be an ASIC such as a GPU, and the first, second, third, and fourth semiconductor dies 100, 200, 300, and 400 may be stack memories such as high-bandwidth memories (HBMs). Each of the stack memories may have a structure in which multiple ICs are stacked, and the multiple ICs may be electrically connected to one another through connection pads, bumps, or through silicon vias (TSVs).

The fifth semiconductor die 20 may include fifth lower pads 25. The fifth lower pads 25 may be used to electrically connect the fifth semiconductor die 20 and other elements. For example, the fifth lower pads 25 may be exposed from the bottom surface of the fifth semiconductor die 20.

The first, second, third, and fourth semiconductor dies 100, 200, 300, and 400 may be electrically connected to other elements through first lower connection pads (e.g., “142” of FIG. 2).

The fifth semiconductor die 20 and the first, second, third, and fourth semiconductor dies 100, 200, 300, and 400 may be mounted on the top surface of the interposer structure 800. For example, second connection members 27 may be formed between the interposer structure 800 and the fifth semiconductor die 20. The second connection members 27 may connect some of the second interposer pads 804 and the fifth lower pads 25. Accordingly, the interposer structure 800 and the fifth semiconductor die 20 may be electrically connected to each other.

Also, for example, the first lower connection pads 150 and the first connection bumps 170 may be formed between the interposer structure 800 and the first, second, third, and fourth semiconductor dies 100, 200, 300, and 400. The first connection bumps 170 may connect some of the second interposer pads 804 and the first lower connection pads 150. Accordingly, the interposer structure 800 and the first, second, third, and fourth semiconductor dies 100, 200, 300, and 400 may be electrically connected to one another. However, the present disclosure is not limited to this example. Alternatively, the interposer structure 800 and the first, second, third, and fourth semiconductor dies 100, 200, 300, and 400 may be electrically connected to one another through another substrate and a wiring structure between the interposer structure 800 and the first, second, third, and fourth semiconductor dies 100, 200, 300, and 400.

The second connection members 27 may be solder bumps including a low-melting-point metal such as, for example, Sn and an alloy of Sn, but the present disclosure is not limited thereto. The second connection members 27 may have various shapes such as a land shape, a ball shape, a pin shape, or a pillar shape. The second connection members 27 may also include under-bump metallurgy (UBM).

The second connection members 27 may be formed as single layers or multilayers. The second connection members 27 may be formed as single layers including, for example, Sn—Ag solder or Cu. Alternatively, the second connection members 27 may be formed as multilayers including, for example, a Cu filler and solder. The number of second connection members 27, the distance between the second connection members 27, and the layout of the second connection members 27 are not particularly limited and may vary depending on the design of the semiconductor package.

Some of the wiring patterns 840 may electrically connect the fifth semiconductor die 20 and the first, second, third, and fourth semiconductor dies 100, 200, 300, and 400.

In some embodiments, second underfill 30 may be formed between the interposer structure 800 and the fifth semiconductor die 20. The second underfill 30 may fill the space between the interposer structure 800 and the fifth semiconductor die 20. The second underfill 30 may cover the second connection members 27.

The second underfill 30 may prevent breakage of the interposer structure 800 by fixing the interposer structure 800 on the fifth semiconductor die 20. The second underfill 30 may include, for example, an insulating polymer material such as an EMC, but the present disclosure is not limited thereto.

The mold film 700 may be on the interposer structure 800. The mold film 700 may be provided between the fifth semiconductor die 20 and the first, second, third, and fourth semiconductor dies 100, 200, 300, and 400. The mold film 700 may separate the fifth semiconductor die 20 from the first, second, third, and fourth semiconductor dies 100, 200, 300, and 400.

The mold film 700 may include an insulating polymer material such as, for example, an EMC, but the present disclosure is not limited thereto. The mold film 700 may include a different material from the first and second underfills 860 and 30. For example, the first and second underfills 860 and 30 may include an insulating material with greater fluidity than the mold film 700. Accordingly, the first and second underfills 860 and 30 can fill (e.g., can fill with greater efficiency) the narrow space between the base substrate 41 and the interposer structure 800 or between the interposer structure 800, the fifth semiconductor die 20, and the first, second, third, and fourth semiconductor dies 100, 200, 300, and 400.

The semiconductor package may further include an adhesive film 910 and a heat slug 920.

The adhesive film 910 may be provided on the mold film 700. The adhesive film 910 may be provided on the fifth semiconductor die 20 and the first, second, third, and fourth semiconductor dies 100, 200, 300, and 400. The adhesive film 910 may be in contact with the top surface of the mold film 700. The adhesive film 910 may be in contact with the top surface of the fifth semiconductor die 20, the top surfaces of the first, second, third, and fourth semiconductor dies 100, 200, 300, and 400, and the top surface of the heat sink 600. The adhesive film 910 may bond and affix the mold film 700, the fifth semiconductor die 20, the first, second, third, and fourth semiconductor dies 100, 200, 300, and 400, and the heat slug 920 together. The adhesive film 910 may include an adhesive material. For example, the adhesive film 910 may include a curable polymer. The adhesive film 910 may include, for example, an epoxy polymer.

The heat slug 920 may be on the base substrate 41. The heat slug 920 may cover the fifth semiconductor die 20, the first, second, third, and fourth semiconductor dies 100, 200, 300, and 400, and the heat sink 600. The heat slug 920 may include a metal material, but the present disclosure is not limited thereto.

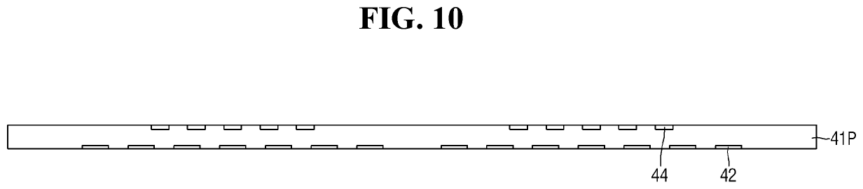

FIGS. 10 through 17 are cross-sectional views illustrating a method of fabricating a semiconductor package according to some embodiments of the present disclosure. For convenience, the embodiment of FIGS. 10 through 17 will hereinafter be described with focus mainly on the embodiment of FIGS. 1 and 2.

Referring to FIG. 10, a pre-base substrate 41P may be provided.

Bottom pads 42 may be on the bottom surface of the pre-base substrate 41P. Top pads 44 may be on the top surface of the pre-base substrate 41P.

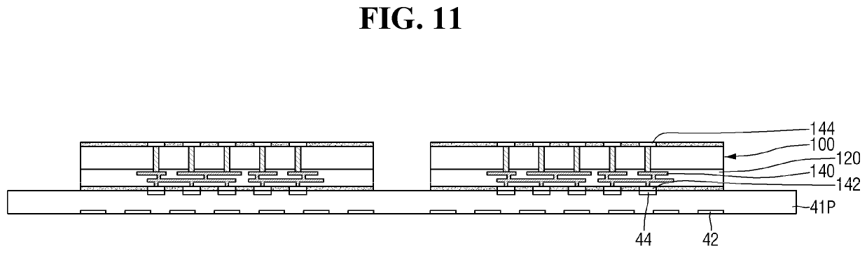

Referring to FIG. 11, first semiconductor dies 100 may be formed on the pre-base substrate 41P.

The first semiconductor dies 100 may be such that first lower connection pads 142 of each of the first semiconductor dies 100 may face the top pads 44 of the pre-base substrate 41P. The first lower connection pads 142 may be in contact with the top pads 44.

The first lower connection pads 142 may be between the first semiconductor dies 100 and the pre-base substrate 41P.

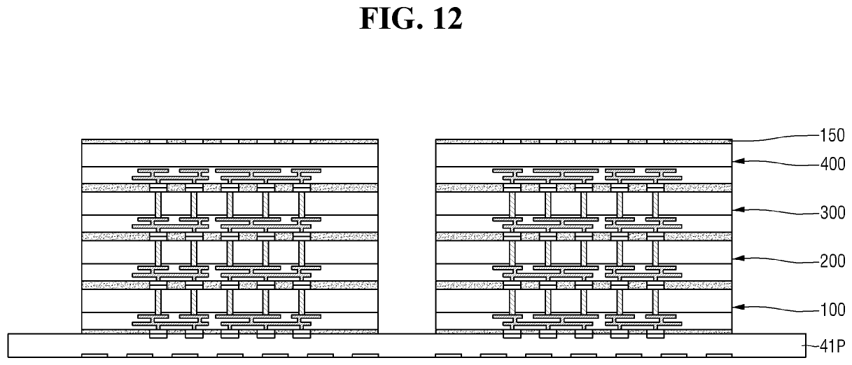

Referring to FIG. 12, second semiconductor dies 200, third semiconductor dies 300, and fourth semiconductor dies 400 are sequentially formed on the pre-base substrate 41P and the first semiconductor die 100.

Specifically, the second semiconductor dies 200 may be stacked on the first semiconductor dies 100. First upper connection pads (“144” of FIG. 2) of each of the first semiconductor dies 100 and second lower connection pads (“242” of FIG. 2) of each of the second semiconductor dies 200 may be in contact with one another and may be surrounded by insulating layers 150.

Similarly, the third semiconductor dies 300 and the fourth semiconductor dies 400 may be stacked on the second semiconductor dies 200.

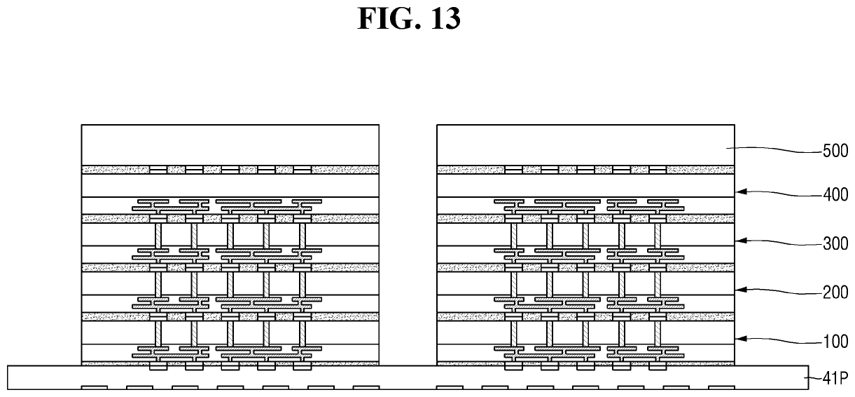

Referring to FIG. 13, dummy dies 500 may be formed on the fourth semiconductor dies 400.

Fifth lower connection pads (“542” of FIG. 2) of each of the dummy dies 500 and fourth upper connection pads (“444” of FIG. 2) of each of the fourth semiconductor dies 400 may be in contact with one another and may be surrounded by insulating layers 150. The dummy dies 500 may not include memories.

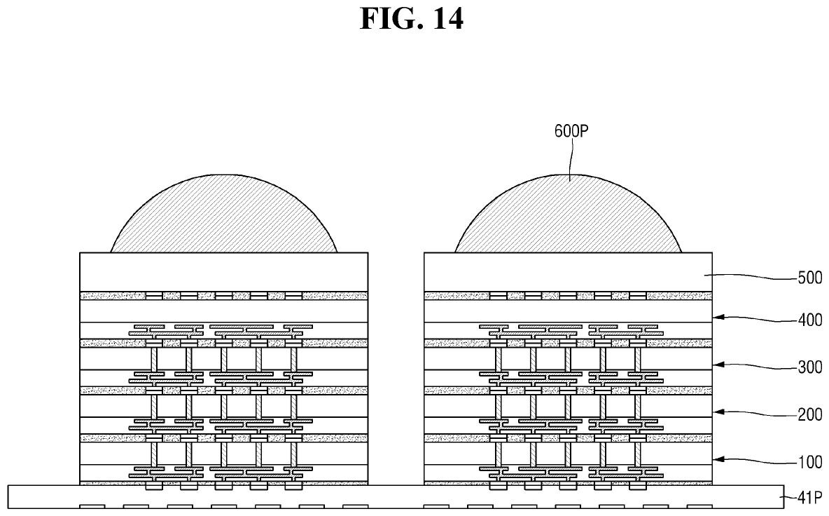

Referring to FIG. 14, pre-heat sinks 600P may be formed on the dummy dies 500.

The pre-heat sinks 600P may have a hemispherical shape. The pre-heat sinks 600P may be arranged so as to protrude from the top surfaces of the dummy dies 500. The bottom surfaces of the pre-heat sinks 600P may be smaller than the top surfaces of the dummy dies 500. The bottom surfaces of the pre-heat sinks 600P may be in direct contact with the top surfaces of the dummy dies 500. The pre-heat sinks 600P may include a metal material.

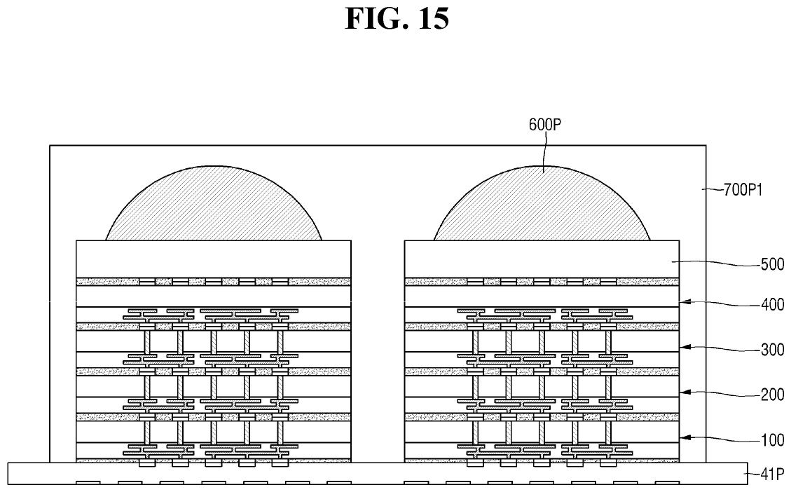

Referring to FIG. 15, a first pre-mold film 700P1 may be formed.

The first pre-mold film 700P1 may be formed on the pre-base substrate 41P. The first pre-mold film 700P1 may cover the first semiconductor dies 100, the second semiconductor dies 200, the third semiconductor dies 300, the fourth semiconductor dies 400, the dummy dies 500, and the pre-heat sinks 600P. Specifically, the first pre-mold film 700P1 may surround the side surfaces of each of the first semiconductor dies 100, the second semiconductor dies 200, the third semiconductor dies 300, and the fourth semiconductor dies 400. The first pre-mold film 700P1 may cover the side surfaces of each of the dummy dies 500 and parts of the top surfaces of the dummy dies 500. The first pre-mold film 700P1 may generally cover the top surfaces of the pre-heat sinks 600P.

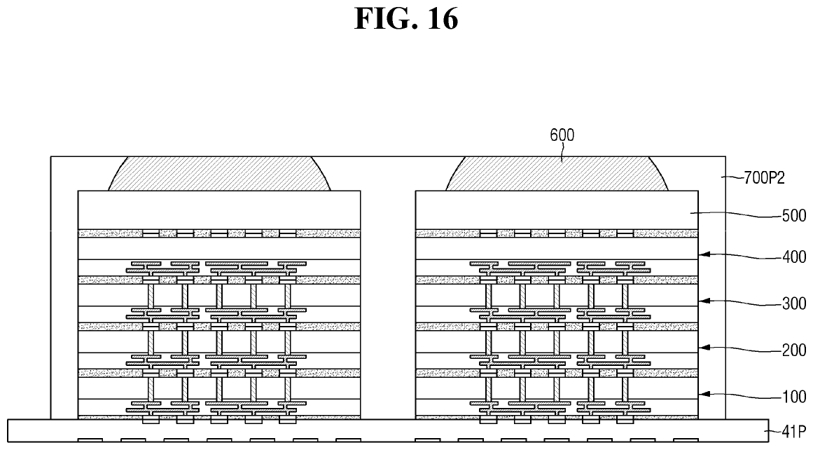

Referring to FIG. 16, heat sinks 600 and a second pre-mold film 700P2 may be formed.

Part of the first pre-mold film 700P1 and parts of the pre-heat sinks 600P may be removed. The top surfaces of the heat sinks 600 may not be covered by the second pre-mold film 700P2. That is, the top surfaces of the heat sinks 600 may be exposed from the second pre-mold film 700P2. The top surfaces of the heat sinks 600 may be on the same plane as the top surface of the second pre-mold film 700P2.

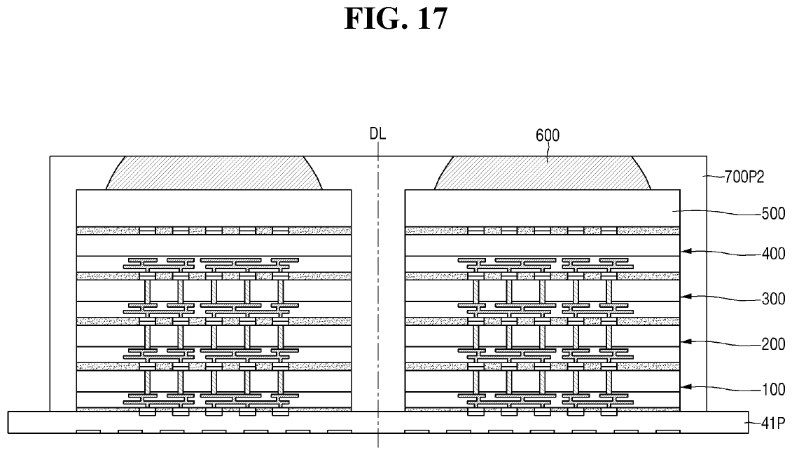

Referring to FIG. 17, a plurality of semiconductor packages may be obtained by cutting along a dicing line DL.

The second pre-mold film 700P2 and the pre-base substrate 41P may be cut along the dicing line DL.

In concluding the detailed description, those skilled in the art will appreciate that many variations and modifications may be made to the preferred embodiments without substantially departing from the principles of the present inventive concepts. Therefore, the disclosed preferred embodiments of the invention are used in a generic and descriptive sense only and not for purposes of limitation.

What is claimed is:

1. A semiconductor package comprising:
a first semiconductor die including a first top surface and a first bottom surface, which is opposite to the first top surface;
a second semiconductor die including a second bottom surface, which faces the first top surface, and a second top surface, which is opposite to the second bottom surface;
a dummy die on the second semiconductor die;
a heat sink on the dummy die and including a metal material; and
a mold film on side surfaces of each of the first semiconductor die, the second semiconductor die, the dummy die, and the heat sink,
wherein side surfaces of the heat sink protrude outwardly from a central axis of the heat sink and are convex toward an outside of the semiconductor package.

2. The semiconductor package of claim 1, wherein:
the first semiconductor die includes upper connection pads, which are on the first top surface,
the second semiconductor die includes first lower connection pads, which are on the second bottom surface, and
the upper connection pads and the first lower connection pads contact one another.

3. The semiconductor package of claim 1, wherein:
the first semiconductor die includes upper connection pads, which are on the first top surface,
the second semiconductor die includes first lower connection pads, which are on the second bottom surface, and
the semiconductor package further includes connection bumps, which are between the upper connection pads and the first lower connection pads, and contact the upper connection pads and the first lower connection pads.

4. The semiconductor package of claim 1, wherein in a plan view, a top surface of the mold film surrounds a top surface of the heat sink.

5. The semiconductor package of claim 1, wherein a bottom surface of the heat sink contacts a top surface of the dummy die.

6. The semiconductor package of claim 1, wherein a thickness of the dummy die is greater than or is equal to thicknesses of the first and second semiconductor dies.

7. The semiconductor package of claim 6, wherein the thickness of the dummy die is one to five times the thickness of the second semiconductor die.

8. The semiconductor package of claim 6, wherein the thicknesses of the first and second semiconductor dies are equal.

9. The semiconductor package of claim 1, wherein
the dummy die includes a vertical electrode, which extends through part of the dummy die, and
the vertical electrode is spaced apart vertically from a bottom surface of the heat sink.

10. The semiconductor package of claim 9, wherein a distance between a top surface of the vertical electrode and the bottom surface of the heat sink is 5 μm or greater.

11. The semiconductor package of claim 9, wherein
the dummy die includes second lower connection pads, which are on a bottom surface of the dummy die, and
the vertical electrode is in contact with, and electrically connected to, one of the second lower connection pads.

12. The semiconductor package of claim 1, wherein a top surface of the heat sink is smaller in one or more dimensions than a bottom surface of the heat sink.

13. The semiconductor package of claim 1, wherein a width in a first horizontal direction of a top surface of the heat sink is 50% to 90% of a width in the first horizontal direction of a bottom surface of the heat sink.

14. The semiconductor package of claim 1, wherein
the first and second semiconductor dies include memory devices, and
the dummy die does not include a memory device.

15. The semiconductor package of claim 1, wherein a top surface of the mold film and a top surface of the heat sink are coplanar.

16. A semiconductor package comprising:
a first semiconductor die including a memory;
a second semiconductor die including a memory and on the first semiconductor die;
a dummy die on the second semiconductor die and not including a memory;
a heat sink on the dummy die and including a metal material; and
a mold film on side surfaces of each of the first semiconductor die, the second semiconductor die, the dummy die, and the heat sink,
wherein a width of the heat sink decreases away from a top surface of the dummy die, and
wherein side surfaces of the heat sink are curved.

17. The semiconductor package of claim 16, wherein a top surface of the mold film and a top surface of the heat sink are coplanar.

18. The semiconductor package of claim 16, wherein a thickness of the dummy die is at least equal to thicknesses of the first and second semiconductor dies.

19. The semiconductor package of claim 16, wherein a top surface of the heat sink has a rectangular shape with rounded corners.

20. A semiconductor package comprising:
a first semiconductor die including a memory, a first top surface, and a first bottom surface that is opposite to the first top surface;
upper connection pads on the first top surface;
a second semiconductor die including a memory, a second bottom surface, which faces the first top surface, and a second top surface, which is opposite to the second bottom surface;
lower connection pads on the second bottom surface and in contact with the upper connection pads;
a dummy die on the second semiconductor die and not including a memory;
a heat sink on the dummy die and in contact with a top surface of the dummy die, the heat sink including a metal material; and
a mold film on side surfaces of each of the first semiconductor die, the second semiconductor die, the dummy die, and the heat sink,
wherein a top surface of the mold film and a top surface of the heat sink are coplanar, and
wherein side surfaces of the heat sink protrude outwardly from a central axis of the heat sink and are convex toward an outside of the semiconductor package.
